(19) United States
(12) Patent Application Publication
(10) Pub. No.: US 2025/0183851 A1
(43) Pub. Date: Jun. 5, 2025

(54) DOHERTY AMPLIFIER CIRCUIT

(71) Applicant: Sumitomo Electric Device Innovations, Inc., Yokohama-shi (JP)

(72) Inventor: Takashi SUMIYOSHI, Yokohama-shi (JP)

(73) Assignee: Sumitomo Electric Device Innovations, Inc., Yokohama-shi (JP)

(21) Appl. No.: 18/956,958

(22) Filed: Nov. 22, 2024

(30) Foreign Application Priority Data
Nov. 30, 2023 (JP) 2023-202851

(51) Int. Cl. H03F 1/02

(52) U.S. Cl. CPC H03F 1/0288; H03F 2200/165; H03F 2200/222; H03F 2200/387

(57) ABSTRACT

A Doherty amplifier circuit includes a division node that divides an input signal into a first signal and a second signal, a main amplifier that amplifies the first signal and outputs an amplified first signal as a third signal, a first peak amplifier that amplifies the second signal and outputs an amplified second signal as a fourth signal, a combination node that combines the third signal and the fourth signal and outputs a combined signal to an output terminal as an output signal, and a notch filter that is connected between the division node and the first peak amplifier and suppresses a signal at a center frequency of an operating band.

### CROSS REFERENCE TO RELATED APPLICATIONS

This application claims priority based on Japanese Patent Application No. 2023-202851 filed on Nov. 30, 2023, and the entire contents of the Japanese patent applications are incorporated herein by reference.

### FIELD

A certain aspect of the embodiments is related to a Doherty amplifier circuit.

### BACKGROUND

There has been known an N-way Doherty amplifier circuit (N is 3 or more) using a main amplifier and two or more peak amplifiers (for example, Patent Document 1: U.S. Pat. No. 8,022,760, and Patent document 2: U.S. Pat. No. 10,601,375).

### SUMMARY

A Doherty amplifier circuit according to the present disclosure includes a division node that divides an input signal into a first signal and a second signal; a main amplifier that amplifies the first signal and outputs an amplified first signal as a third signal; a first peak amplifier that amplifies the second signal and outputs an amplified second signal as a fourth signal; a combination node that combines the third signal and the fourth signal and outputs a combined signal to an output terminal as an output signal; and a notch filter that is connected between the division node and the first peak amplifier and suppresses a signal at a center frequency of an operating band.

### BRIEF DESCRIPTION OF DRAWINGS

FIG. 1 is a block diagram of a Doherty amplifier circuit according to a first embodiment.

FIG. 2 is a diagram illustrating an example of a notch filter in the first embodiment.

FIG. 3 is a schematic diagram illustrating a probability with respect to an output power Pout, an output power Pout of each amplifier with respect to an input power Pin, a gain of each amplifier with respect to an input power Pin, and an overall gain with respect to an input power Pin in the first embodiment.

FIG. 4 is a diagram illustrating a power with respect to a frequency in a first comparative example.

FIG. 5 is a diagram illustrating a power with respect to a frequency in a first embodiment.

### DETAILED DESCRIPTION OF EMBODIMENTS

However, in the Doherty amplifier circuit, an impedance converter is used as a combiner. A phase adjuster is provided to adjust the phase fluctuation caused by the impedance converter. This results in a narrow band.

An object of the present disclosure is to provide a broadband.

### Details of Embodiments of the Present Disclosure

First, the contents of the embodiments of this disclosure are listed and explained.

(1) A Doherty amplifier circuit according to the present disclosure includes a division node that divides an input signal into a first signal and a second signal; a main amplifier that amplifies the first signal and outputs an amplified first signal as a third signal; a first peak amplifier that amplifies the second signal and outputs an amplified second signal as a fourth signal; a combination node that combines the third signal and the fourth signal and outputs a combined signal to an output terminal as an output signal; and a notch filter that is connected between the division node and the first peak amplifier and suppresses a signal at a center frequency of an operating band. This makes it possible to achieve a wide band.

(2) In the above (1), the Doherty amplifier circuit may further include a second peak amplifier that amplifies a fifth signal and outputs an amplified fifth signal as a sixth signal. The division node may divide the input signal into the first signal, the second signal, and the fifth signal, the combination node may combine the third signal, the fourth signal, and the sixth signal, and output a combined signal to the output terminal as the output signal, and an input power of the input signal that turns on the first peak amplifier may be smaller than an input power of the input signal that turns on the second peak amplifier. This makes it possible to achieve a wide band.

(3) In the above (1) or (2), when an input power of the input signal is a power at which the main amplifier and the first peak amplifier operate, a power of the third signal at the center frequency in the combination node may be larger than a power of the third signal at frequencies at both ends of the operating band in the combination node, and a power of the fourth signal at the center frequency in the combination node may be smaller than a power of the fourth signal at frequencies at both ends of the operating band in the combination node. This makes it possible to achieve a wide band.

(4) In the above (3), when the input power of the input signal is the power at which the main amplifier and the first peak amplifier operate, an absolute value of a difference between an output power of the output signal at the center frequency and an output power at frequencies at both ends of the operating band may be smaller than an absolute value of a difference between the power of the third signal at the center frequency at the combination node and the power of the third signal at frequencies at both ends of the operating band at the combination node. This makes it possible to achieve a wide band.

(5) In the above (4), when the input power of the input signal is the power at which the main amplifier and the first peak amplifier operate, the absolute value of the difference between the output power of the output signal at the center frequency and the output power at frequencies at both ends of the operating band may be smaller than an absolute value of a difference between an power of the fourth signal at the center frequency and an power of the fourth signal at frequencies at both ends of the operating band at the combination node. This makes it possible to achieve a wide band.

(6) In any of the above (1) to (5), a notch filter for suppressing a signal at the center frequency may not be connected between the division node and the main amplifier. This allows miniaturization.

(7) In the above (2), the notch filter for suppressing the signal at the center frequency may not be connected between the division node and the second peak amplifier. This allows miniaturization.

(8) In any one of the above (1) to (7), a ¼ wavelength line may be connected in series in a path extending from the division node to the combination node through the main amplifier. This allows miniaturization.

Specific examples of a Doherty amplifier circuit according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

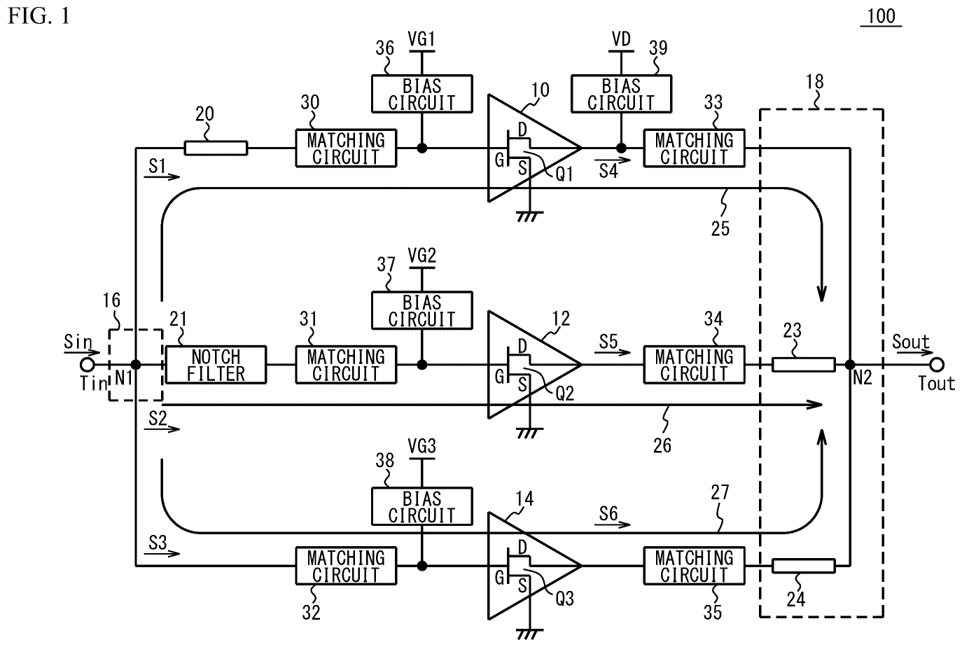

As an example of the Doherty amplifier circuit, a description will be given of a high-output high-frequency amplifier circuit used in a base station of mobile communication. In this case, the frequency of the high-frequency signal is, for example, 0.5 GHz or more and 10 GHz or less. FIG. 1 is a block diagram of the Doherty amplifier circuit according to a first embodiment.

As illustrated in FIG. 1, in a Doherty amplifier circuit 100, a main amplifier 10, a peak amplifier 12 (first peak amplifier), and a peak amplifier 14 (second peak amplifier) are connected in parallel between a division node N1 of a divider 16 and a combination node N2 of a combiner 18. Paths 25 to 27 are paths from the division node N1 to the combination node N2 through the main amplifier 10 and the peak amplifiers 12 and 14, respectively. Thus, the Doherty amplifier circuit 100 is a three-way amplifier circuit. The Doherty amplifier circuit may be an N-way Doherty amplifier circuit having one peak amplifier or three or more peak amplifiers.

A high-frequency signal is input to the input terminal Tin as an input signal Sin. The divider 16 divides the input signal Sin input to the input terminal Tin into the signals S1 (first signal), S2 (second signal), and S3 (fifth signal). The divider 16 is, for example, a Wilkinson divider. The divider 16 has the division node N1 at which the signals S1, S2 and S3 are divided.

The path 25 includes a phase adjuster 20, a matching circuit 30, a bias circuit 36, the main amplifier 10, a bias circuit 39, and a matching circuit 33. The path 26 includes a notch filter 21, a matching circuit 31, a bias circuit 37, the peak amplifier 12, a matching circuit 34, and an impedance converter 23. The path 27 includes a matching circuit 32, a bias circuit 38, the peak amplifier 14, a matching circuit 35, and an impedance converter 24.

The matching circuits 30 to 32 match impedances viewed from the divider 16 toward the matching circuits 30 to 32 with impedances viewed from the matching circuits 30 to 32 toward the main amplifier 10 and the peak amplifiers 12 and 14, respectively. The bias circuits 36 to 38 supply gate bias voltages VG1 to VG3 to the gates G of the main amplifier 10 and the peak amplifiers 12 and 14, respectively.

The phase adjuster 20 adjusts the phase of the signal S1 in order to align the phases of the signals S5 and S6 changed by the impedance converters 23 and 24 with the phase of the signal S4. The notch filter 21 is a filter for suppressing a signal at a center frequency of an operating band.

The main amplifier 10 and the peak amplifiers 12 and 14 amplify the signals S1, S2 and S3, respectively, and output the amplified signals S4 (third signal), S5 (fourth signal) and S6 (sixth signal), respectively. The bias circuit 39 supplies a drain bias voltage VD to the drains D of the main amplifier 10 and the peak amplifiers 12 and 14. The matching circuits 33 to 35 match impedances as viewed from the matching circuits 33 to 35 toward the main amplifier 10 and the peak amplifiers 12 and 14 with impedances as viewed from the combiner 18 toward the matching circuits 33 to 35, respectively.

The combiner 18 includes the combination node N2 and the impedance converters 23 and 24. The impedance converter 23 has a first end electrically connected to the peak amplifier 12 through the matching circuit 34 and a second end electrically connected to the combination node N2. The impedance converter 24 has a first end electrically connected to the peak amplifier 14 through the matching circuit 35 and a second end electrically connected to the combination node N2. The combination node N2 combines the signals S4 to S6 and outputs the combined signal to the output terminal Tout as an output signal Sout.

The impedance converters 23 and 24 convert impedances on the real axis of the Smith chart viewed from the matching circuits 34 and 35 toward the impedance converters 23 and 24 into impedances at different locations on the real axis of the Smith chart viewed from the impedance converters 23 and 24 toward the combination node N2. When the peak amplifier 12 does not operate, the impedance converter 23 sets the impedance viewed from the combination node N2 toward the peak amplifier 12 to infinity. When the peak amplifier 14 does not operate, the impedance converter 24 sets the impedance viewed from the combination node N2 toward the peak amplifier 14 to infinity.

The phase adjuster 20 and the impedance converters 23 and 24 are transmission lines, such as microstrip lines or coplanar lines, and are ¼ wavelength lines at the center frequency of the operating band. The electrical length of the ¼ wavelength line is not strictly limited to the ¼ wavelength. The ¼ wavelength lines only need to have electrical lengths that serve as the impedance converters 23 and 24. For example, the electric length of the ¼ wavelength line may be 3/16 wavelength or more and 5/16 wavelength or less, or 7/32 wavelength or more and 9/32 wavelength or less. The impedance on the real axis in the Smith chart does not have to be strictly on the real axis (i.e., a reactance component is 0). An absolute value of the reactance component of the impedance may be 0.2 times or less or 0.1 times or less a resistance component.

The main amplifier 10 and the peak amplifiers 12 and 14 include transistors Q1 to Q3, respectively. The transistors Q1 to Q3 are, for example, FETs (Field Effect Transistors), GaN HEMTs (Gallium Nitride High Electron Mobility Transistors) or LDMOS (Laterally Diffused Metal Oxide Semiconductors). The sources S of the transistors Q1 to Q3 are grounded, the signals S1 to S3 are input to the gates G, and the signals S4 to S6 are output from the drains D.

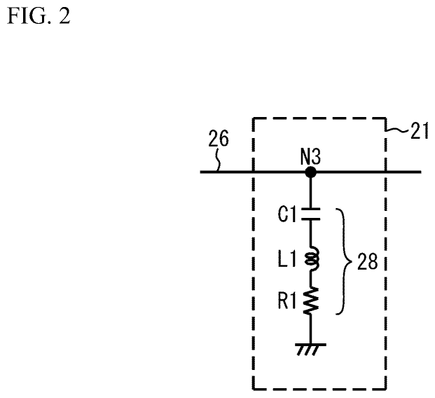

FIG. 2 is a diagram illustrating an example of a notch filter in the first embodiment. As illustrated in FIG. 2, the notch filter 21 includes a series resonant circuit 28 that is shunt-connected to a node N3 of the path 26. The series resonant circuit 28 includes a capacitor C1, an inductor L1, and a resistor RI connected in series between the node N3 and a reference potential such as ground. By setting the resonance frequency of the series resonance circuit 28 to a center frequency f0, the signal at the center frequency f0 transmitted through the path 26 is suppressed. The notch filter 21 may be an LC parallel resonant circuit or an LCR parallel resonant circuit provided in series with the path 26. The circuit configuration of the notch filter 21 can be designed as appropriate.

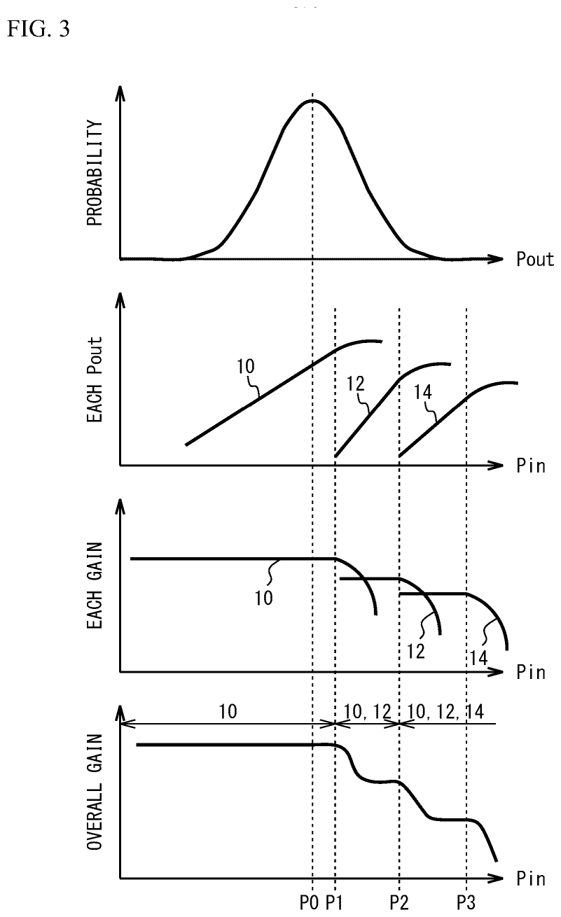

FIG. 3 is a schematic diagram illustrating a probability with respect to an output power Pout, an output power Pout of each amplifier with respect to an input power Pin, a gain of each amplifier with respect to an input power Pin, and an overall gain with respect to an input power Pin in the first embodiment.

The probability is a probability of a modulated wave signal of the high-frequency signal for mobile communication amplified by the Doherty amplifier circuit 100. That is, it is a probability that the Doherty amplifier circuit 100 outputs a certain output power Pout. Each Pout is an output power Pout of each of the main amplifier 10 and the peak amplifiers 12 and 14. Each gain is a power gain of each of the main amplifier 10 and the peak amplifiers 12 and 14. The overall gain is a power gain of the output power Pout of the output signal Sout with respect to the input power Pin of the input signal Sin. The Pin and Pout are expressed in dB. The gain of the main amplifier 10 at a power P1 or less of each gain is larger than the gain of the peak amplifier 12 at the power P1 or more and a power P2 or less. That is, the inclination of Pout with respect to the input power Pin at the power P1 or less of the main amplifier 10 is larger than the inclination of Pout with respect to the input power Pin at the power P1 or more and P2 or less of the peak amplifier 12. However, FIG. 3 is a schematic diagram, and illustrates that the inclination of Pout with respect to the input power Pin at the power P1 or less of the main amplifier 10 is smaller than the inclination of Pout with respect to the input power Pin at the power P1 or more and P2 or less of the peak amplifier 12.

As illustrated in FIG. 3, when the output power Pout is the power P0, the probability of the modulated wave is maximum. That is, when the modulated wave signal is output, the time when the output power Pout is the power P0 is the longest. The main amplifier 10 is an A class or AB class amplifier, and the peak amplifiers 12 and 14 are C class amplifiers. The input power Pin at which the peak amplifier 12 is turned on is larger than the input power Pin at which the main amplifier 10 is turned on, and the input power Pin at which the peak amplifier 14 is turned on is larger than the input power Pin at which the peak amplifier 12 is turned on. Such an operation can be realized by making the gate bias voltage VG2 of the transistor Q2 larger in negative value than the gate bias voltage VG1 of the transistor Q1, and making the gate bias voltage VG3 of the transistor Q3 larger in negative value than the gate bias voltage VG2 of the transistor Q2.

The input power of the input signal Sin at which the main amplifier 10 turns on is smaller than the input power at which the peak amplifier 12 turns on. The input power of the input signal Sin at which the peak amplifier 12 turns on is smaller than the input power at which the peak amplifier 14 turns on. The main amplifier 10 operates, but the peak amplifiers 12 and 14 do not operate, until the input power Pin of the input signal Sin becomes large, the input power Pin exceeds the power P0, and the power P1 is reached. When the input power Pin is equal to or less than the power P1, the output power Pout of the main amplifier 10 increases linearly as the input power Pin increases. Therefore, when the input power Pin is equal to or less than the power P0, each gain and the overall gain are substantially constant.

When the input power Pin is equal to or greater than the power P1 and equal to or less than the power P2, the main amplifier 10 and the peak amplifier 12 operate, but the peak amplifier 14 does not operate. In this range, the main amplifier 10 is saturated. Therefore, the gain of the main amplifier 10 is reduced. This also reduces the overall gain. Since the peak amplifier 12 operates in class C, the gain of the peak amplifier 12 between the powers P1 and P2 is lower than the gain of the main amplifier 10 at the power P1 or lower. The saturation power of the peak amplifier 12 is smaller than the saturation power of the main amplifier 10.

When the input power Pin is equal to or greater than the power P2 and equal to or less than the power P3, all of the main amplifier 10 and the peak amplifiers 12 and 14 operate. In this range, the peak amplifier 12 is saturated in addition to the main amplifier 10. Therefore, the gain of the peak amplifier 12 is reduced. This also reduces the overall gain. Since the peak amplifier 14 is negatively larger than the operating point of the peak amplifier 12, the gain of the peak amplifier 14 between the powers P2 and P3 is lower than the gain of the peak amplifier 12 between the powers P1 and P2. The saturation power of the peak amplifier 14 is smaller than the saturation power of the peak amplifier 12.

When the input power Pin is equal to or greater than the power P3, the peak amplifier 14 is saturated in addition to the main amplifier 10 and the peak amplifier 12. Therefore, the gain of the peak amplifier 14 is reduced. This also reduces the overall gain.

The product of the probability and the overall gain corresponds to the gain of the modulated wave. To improve the gain of the modulated wave, the overall gain at Pout with high probability is improved.

### First Comparative Example

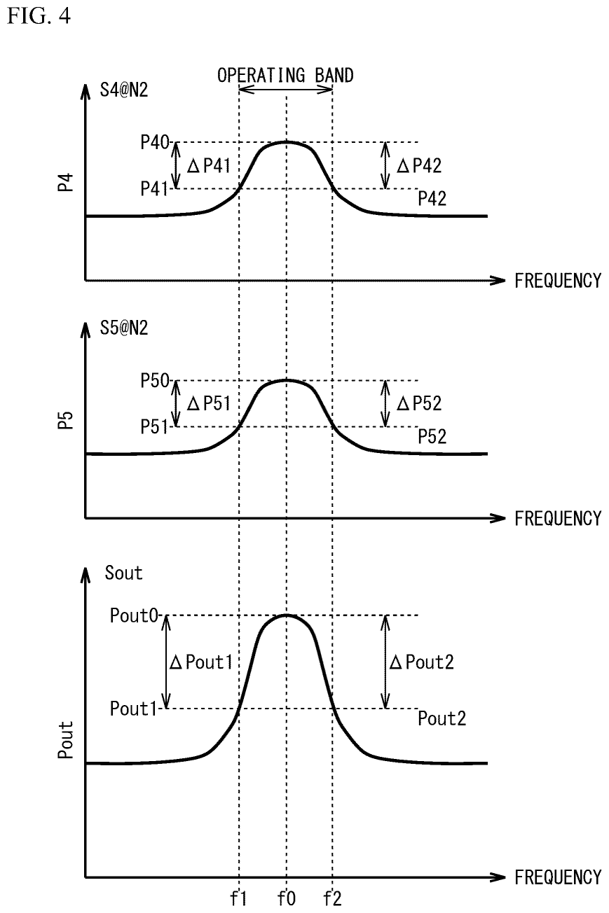

In the first comparative example, the notch filter 21 is not provided. The other configuration of the first comparative example is the same as that of the first embodiment. FIG. 4 is a diagram illustrating a power with respect to a frequency in the first comparative example. FIG. 4 corresponds to a case where the input power Pin is the power P2. A power P4 indicates the power of the signal S4 at the combination node N2. A power P5 indicates the power of the signal S5 at the combination node N2. The output power Pout indicates the power of the output signal Sout. The center frequency f0 indicates the center frequency of the operating band. Frequencies f1 and f2 indicate the low and high frequency ends of the operating band, respectively.

The powers P4 at the center frequency f0, frequencies f1 and f2 are powers P40, P41 and P42, respectively. A difference between the powers P40 and P41 is ΔP41, and a difference between the powers P40 and P42 is ΔP42. The powers P5 at the center frequency f0, frequencies f1 and f2 are powers P50, P51 and P52, respectively. A difference between the powers P50 and P51 is ΔP51, and a difference between the powers P50 and P52 is ΔP52. The output power Pout at the center frequency f0, frequencies f1 and f2 are power Pout0, Pout1 and Pout2, respectively. A difference between the powers Pout0 and Pout1 is ΔPout1, and a difference between the powers Pout0 and Pout2 is ΔPout2.

The phase adjuster 20 is provided in path 25 and the impedance converter 23 is provided in path 26. As the phase adjuster 20 and the impedance converter 23, the ¼ wavelength lines are provided. Therefore, the powers P4 and P5 become narrow bands. Therefore, even if the powers P40 and P50 increase at the center frequency f0, the powers P41, P51, P42, and P52 decrease at the frequencies f1 and f2. This increases ΔP41, ΔP42, ΔP51, and ΔP52.

The output power Pout is a power obtained by combining the powers P4 and P5. Therefore, ΔPout1 is larger than ΔP41 and ΔP51, and ΔPout2 is larger than ΔP42 and ΔP52. Therefore, when the input power Pin is the power P2, the gains in the vicinity of the frequencies f1 and f2 are reduced, and the band is narrowed.

### DESCRIPTION OF EMBODIMENT

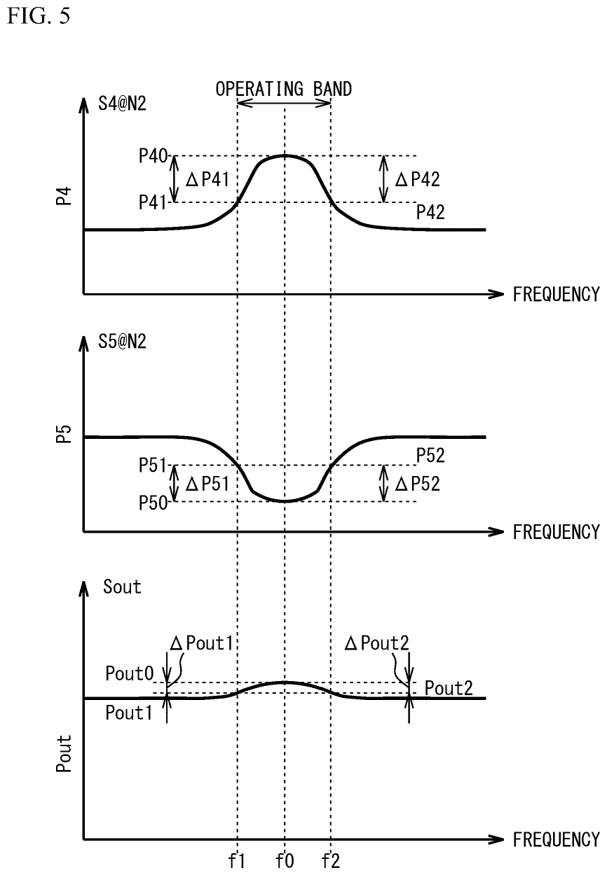

FIG. 5 is a diagram illustrating a power with respect to a frequency in the first embodiment. As illustrated in FIG. 5, in the first embodiment, the notch filter 21 is provided in the path 26. Therefore, at the power P5, the power P50 at the center frequency f0 is smaller than the powers P51 and P52 at the frequencies f1 and f2.

In the output power Pout, a mountain-shaped spectrum of the power P4 with respect to the frequency is compensated by a valley-shaped spectrum of the power P5 with respect to the frequency. As a result, ΔPout1 and ΔPout2 become smaller than ΔPout1 and ΔPout2 of the first comparative example illustrated in FIG. 4. Therefore, when the input power Pin is the power P2, the band can be widened. Even when the input power Pin is the power P3, the band can be widened.

According to the first embodiment, the notch filter 21 for suppressing the signal at the center frequency of the operating band is connected between the division node N1 and the peak amplifier 12. This makes it possible to achieve a wider band in the input power at which the peak amplifier 12 operates.

When the input power Pin of the input signal Sin is the power at which the main amplifier 10 and the peak amplifier 12 operate (for example, when the input power Pin is the power P2 or P3), the power P40 at the center frequency f0 is larger than the powers P41 and P42 at both ends of the operating band in the signal S4 at the combination node N2. In the signal S5 at the combination node N2, the power P50 at the center frequency f0 is smaller than the powers P51 and P52 at both ends of the operating band, respectively. This allows the mountain-shaped spectrum of the signal S4 to be cancelled out by using the valley-shaped spectrum of the signal S5. Therefore, the band width can be increased.

The power P40 may be larger than the powers P41 and P42 by 0.5 dB or more, or may be larger than the powers P42 and P42 by 1 dB or more. The power P50 may be smaller than the power P51 and P52 by 0.5 dB or more, or may be smaller than the power P51 and P52 by 1 dB or more.

At the times of the powers P2 and P3, absolute values of the differences ΔPout1 and ΔPout2 between the power Pout0 at the center frequency f0 of the output power Pout and the powers Pout1 and Pout2 at the frequencies f1 and f2 are smaller than the absolute values of the differences ΔP41 and ΔP42 between the power P40 and the powers P41 and P42, respectively. This allows the mountain-shaped spectrum of the signal S4 to be cancelled out by using the valley-shaped spectrum of the signal S5. Therefore, the band width can be increased.

The absolute values of ΔPout1 and ΔPout2 can be 0.8 times or less and 0.5 times or less the absolute values of ΔP41 and ΔP42.

At the time of the powers P2 and P3, the absolute values of ΔPout1 and ΔPout2 are smaller than the absolute values of the differences Δ P51 and Δ P52 between the power P50 and the powers P51 and P52, respectively. This allows the mountain-shaped spectrum of the signal S4 to be cancelled out by using the valley-shaped spectrum of the signal S5. Therefore, the band width can be increased.

The absolute values of ΔPout1 and ΔPout2 can be 0.8 times or less or 0.5 times or less the absolute values of ΔP51 and ΔP52.

The notch filter for suppressing the signal at the center frequency f0 is not connected between the division node N1 and the main amplifier 10. When the notch filter is provided in the path 25, the insertion loss of the main amplifier 10, which most affects the gain of the modulated wave in FIG. 3, increases. Therefore, the notch filter 21 is provided in the path 26. This makes it possible to suppress a reduction in the gain of the modulated wave and to achieve a wider band.

A notch filter for suppressing the signal at the center frequency f0 may be provided between the division node N1 and the peak amplifier 14. However, as illustrated in FIG. 3, the operation of the peak amplifier 14 does not affect the gain of the modulated wave. Therefore, the size can be reduced by not providing the notch filter in the path 27.

The phase adjuster 20 (e.g. ¼ wavelength line) is connected in series in the path 25 extending from the division node N1 to the combination node N2 through the main amplifier 10. This narrows the band of the output power Pout. Therefore, the notch filter 21 is provided in the path 26, thereby making it possible to achieve a wide band.

Although the three-way Doherty amplifier circuit has been described as an example, a two-way Doherty amplifier circuit in which the peak amplifier 14 and the impedance converter are not provided may be used. Alternatively, an N-way Doherty amplifier circuit in which N is 4 or more may be used. In this case, N−1 peak amplifiers may be provided.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A Doherty amplifier circuit comprising:
a division node that divides an input signal into a first signal and a second signal;
a main amplifier that amplifies the first signal and outputs an amplified first signal as a third signal;
a first peak amplifier that amplifies the second signal and outputs an amplified second signal as a fourth signal;
a combination node that combines the third signal and the fourth signal and outputs a combined signal to an output terminal as an output signal; and
a notch filter that is connected between the division node and the first peak amplifier and suppresses a signal at a center frequency of an operating band.

2. The Doherty amplifier circuit according to claim 1, further comprising:
a second peak amplifier that amplifies a fifth signal and outputs an amplified fifth signal as a sixth signal,
wherein the division node divides the input signal into the first signal, the second signal, and the fifth signal,
the combination node combines the third signal, the fourth signal, and the sixth signal, and outputs a combined signal to the output terminal as the output signal, and
an input power of the input signal that turns on the first peak amplifier is smaller than an input power of the input signal that turns on the second peak amplifier.

3. The Doherty amplifier circuit according to claim 1, wherein
when an input power of the input signal is a power at which the main amplifier and the first peak amplifier operate, a power of the third signal at the center frequency in the combination node is larger than a power of the third signal at frequencies at both ends of the operating band in the combination node, and a power of the fourth signal at the center frequency in the combination node is smaller than a power of the fourth signal at frequencies at both ends of the operating band in the combination node.

4. The Doherty amplifier circuit according to claim 3, wherein
when the input power of the input signal is the power at which the main amplifier and the first peak amplifier operate, an absolute value of a difference between an output power of the output signal at the center frequency and an output power at frequencies at both ends of the operating band is smaller than an absolute value of a difference between the power of the third signal at the center frequency at the combination node and the power of the third signal at frequencies at both ends of the operating band at the combination node.

5. The Doherty amplifier circuit according to claim 4, wherein
when the input power of the input signal is the power at which the main amplifier and the first peak amplifier operate, the absolute value of the difference between the output power of the output signal at the center frequency and the output power at frequencies at both ends of the operating band is smaller than an absolute value of a difference between an power of the fourth signal at the center frequency and an power of the fourth signal at frequencies at both ends of the operating band at the combination node.

6. The Doherty amplifier circuit according to claim 1, wherein
a notch filter for suppressing a signal at the center frequency is not connected between the division node and the main amplifier.

7. The Doherty amplifier circuit according to claim 2, wherein
the notch filter for suppressing the signal at the center frequency is not connected between the division node and the second peak amplifier.

8. The Doherty amplifier circuit according to claim 1, wherein
a ¼ wavelength line is connected in series in a path extending from the division node to the combination node through the main amplifier.
